(19) United States
(12) Patent Application Publication
(10) Pub. No.: US 2023/0354518 A1
(43) Pub. Date: Nov. 2, 2023

(54) ELECTRONIC DEVICE

(71) Applicant: KABUSHIKI KAISHA TOYOTA JIDOSHOKKI, Kariya-shi (JP)

(72) Inventors: Yoshifumi AKITA, Kariya-shi (JP); Tetsuhiko FUJITA, Kariya-shi (JP)

(73) Assignee: KABUSHIKI KAISHA TOYOTA JIDOSHOKKI, Kariya-shi (JP)

(21) Appl. No.: 18/304,873

(22) Filed: Apr. 21, 2023

(30) Foreign Application Priority Data
Apr. 27, 2022 (JP) 2022-073578

(51) Int. Cl. H05K 1/11

(52) U.S. Cl. CPC H05K 1/11

(57) ABSTRACT

An electronic device includes a board and a flat metal plate soldered to the board. The metal plate includes a first main surface, a second main surface opposite to the first main surface, and a side surface that connects the first main surface and the second main surface. The side surface includes a shear surface and a fracture surface. The metal plate is arranged on the board so that the shear surface is closer to the board than the fracture surface. A solder fillet is formed from the board to the shear surface.

### BACKGROUND

### 1. Field

The following description relates to an electronic device.

### 2. Description of Related Art

An electronic device includes a flat metal plate and a board to which the metal plate is soldered. The metal plate includes a first main surface, a second main surface, and a side surface. The first main surface is opposite to the second main surface. The side surface connects the first main surface and the second main surface. The metal plate is arranged on the board so that the first main surface faces the board. A solder fillet is formed from the side surface of the metal plate to the board. In order to form the solder fillet from the side surface of the metal plate to the board, the side surface of the metal plate is plated as disclosed in, for example, Japanese Laid-Open Patent Publication No. 2022-12428.

The plating of the side surface of the metal plate in order to form the solder fillet increases the production cost of the electronic device.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic device including a board and a flat metal plate soldered to the board is provided. The metal plate includes a first main surface, a second main surface opposite to the first main surface, and a side surface that connects the first main surface and the second main surface. The side surface includes a shear surface and a fracture surface. The metal plate is arranged on the board so that the shear surface is closer to the board than the fracture surface. A solder fillet is formed from the board to the shear surface.

Other features and aspects will be apparent from the following detailed description, the drawings, and the claims.

### BRIEF DESCRIPTION OF THE DRAWINGS

FIG. 1 is a partial side view of an electronic device according to one embodiment.

FIG. 2 is a partial plan view of the electronic device shown in FIG. 1.

FIG. 3 is a partial perspective view of the electronic device shown in FIG. 1.

FIG. 4 is a partial cross-sectional view of the electronic device shown in FIG. 1.

FIG. 5 is a partial perspective view showing a shear surface, a fracture surface, and a second plating layer of a metal plate.

FIG. 6 is a perspective view of a metal sheet.

FIG. 7 is a schematic diagram illustrating shearing.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

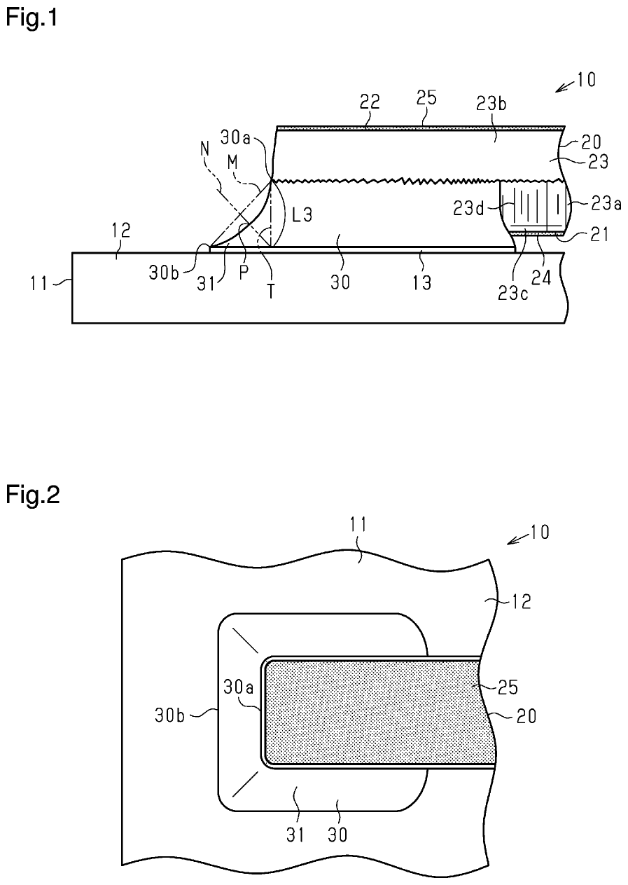

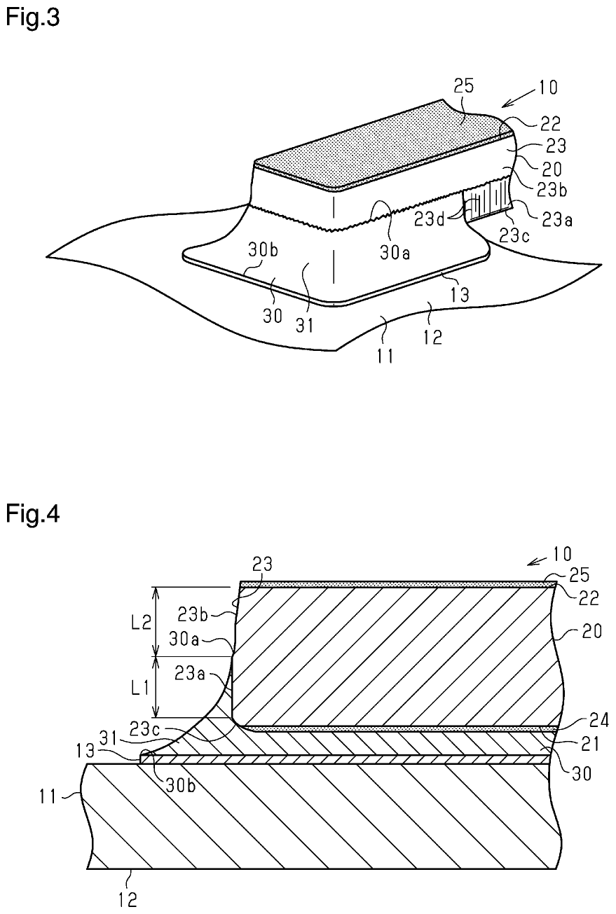

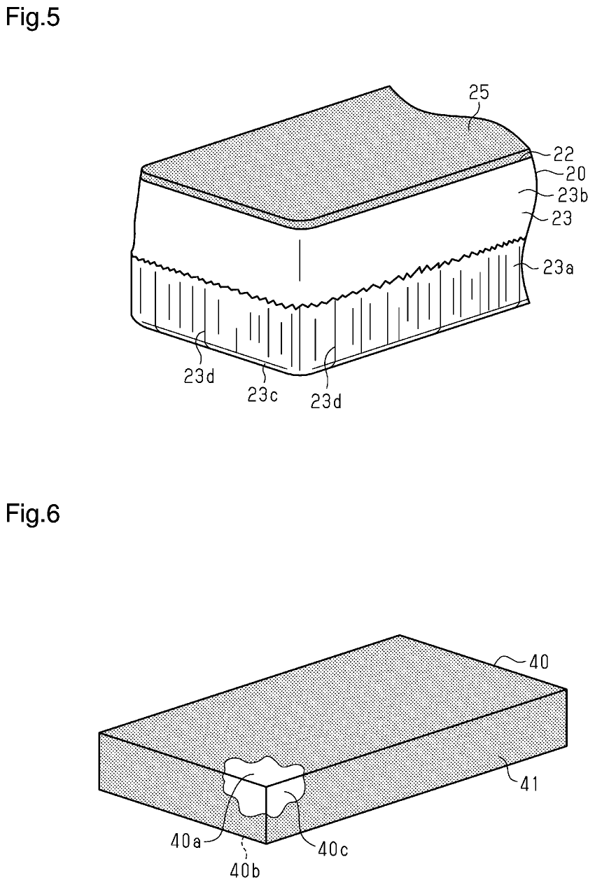

An electronic device 10 according to one embodiment will now be described with reference to FIGS. 1 to 7.

### Electronic Device

As shown in FIGS. 1 to 4, the electronic device 10 includes a board 11 and a metal plate 20. The electronic device 10 is arranged in, for example, a DC-DC converter.

### Board

The board 11 includes an insulative substrate 12 and a conductive pattern 13. The conductive pattern 13 is arranged on a main surface of the insulative substrate 12.

### Metal Plate

The metal plate 20 is flat. The metal plate 20 includes a distal end joined with the conductive pattern 13 by solder 30. The metal plate 20 is made of a metal material having high electric conductivity. For example, the metal plate 20 is made of copper. As will be described later, the metal plate 20 is formed by shearing a plated metal sheet.

The metal plate 20 includes a first main surface 21, a second main surface 22, and a side surface 23. The first main surface 21 and the second main surface 22 are arranged at opposite sides of the metal plate 20 in the thickness direction of the metal plate 20. The thickness direction of the metal plate 20 extends from one of the first main surface 21 and the second main surface 22 to the other one of the first main surface 21 and the second main surface 22. The thickness direction of the metal plate 20 will hereafter be simply referred to as the thickness direction.

The first main surface 21 is plated. The metal plate 20 includes a first plating layer 24 coating the first main surface 21. The second main surface 22 is plated. The metal plate 20 includes a second plating layer 25 coating the second main surface 22.

The first plating layer 24 and the second plating layer 25 are each made of, for example, tin. The first plating layer 24 and the second plating layer 25 may be each made of any one of tin, gold, nickel, and silver, or an alloy combining at least two of these materials.

The side surface 23 connects the first main surface 21 and the second main surface 22. The side surface 23 includes a shear surface 23a and a fracture surface 23b. The side surface 23 also includes a droop surface 23c. The droop surface 23c is curved to connect the first main surface 21 and the shear surface 23a in the thickness direction.

The shear surface 23a connects the droop surface 23c and the fracture surface 23b in the thickness direction. The shear surface 23a and the droop surface 23c have streaks of machining marks 23d extending in the thickness direction. The machining marks 23d are fine grooves.

The fracture surface 23b connects the second main surface 22 and the shear surface 23a in the thickness direction. Although not shown in detail, the fracture surface 23b is rougher than the shear surface 23a. The fracture surface 23b does not have streaks of machining marks 23d. The shear surface 23a and the fracture surface 23b are arranged next to each other in this order in the direction extending from the first main surface 21 to the second main surface 22.

In the description hereafter, L1 denotes the length of the shear surface 23a in the thickness direction, and L2 denotes the length of the fracture surface 23b in the thickness direction.

### Method for Manufacturing Metal Plate

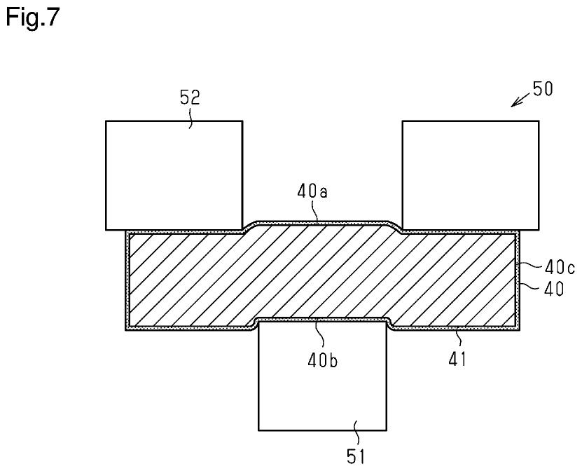

As shown in FIGS. 6 and 7, the metal plate 20 is formed by shearing a metal sheet 40. The two opposite surfaces of the metal sheet 40 in the thickness direction are plated. The metal sheet 40 is larger than the metal plate 20 in plan view. The metal sheet 40 includes a first surface 40a, a second surface 40b, and a connection surface 40c that connects the first surface 40a and the second surface 40b. The first surface 40a and second surface 40b are arranged at opposite sides of the metal sheet 40 in the thickness direction of the metal sheet 40. The thickness direction of the metal sheet 40 extends from one of the first surface 40a and the second surface 40b to the other one of the first surface 40a and the second surface 40b. The thickness direction of the metal sheet 40 is the same as the thickness direction of the metal plate 20.

The first surface 40a, the second surface 40b, and the connection surface 40c of the metal sheet 40 are plated. Thus, a plating layer 41 is formed on the first surface 40a, the second surface 40b, and the connection surface 40c. The first surface 40a forms the first main surface 21 of the metal plate 20. The second surface 40b forms the second main surface 22 of the metal plate 20.

The metal sheet 40 is sheared by a die assembly 50. The die assembly 50 includes a die 51 and punch 52. The punch 52 is shaped to punch out the metal plate 20 from the metal sheet 40.

During shearing, the metal sheet 40 is placed on the die 51. The meta sheet 40 is placed on the die 51 so that the plating layer 41 of the second surface 40b contacts the die 51. Then, the punch 52 presses the metal sheet 40 from the first surface 40a toward the second surface 40b. When the punch 52 presses the metal sheet 40 in the thickness direction, a droop forms at a portion of the metal sheet 40 that contacts the punch 52. The droop forms the droop surface 23c. Further, contact with the punch 52 forms the machining marks 23d on the droop surface 23c.

As the punch 52 further presses the metal sheet 40 in the thickness direction, the shear surface 23a is formed by the cut section of the metal sheet 40 and cracks are formed in the metal sheet 40. Further, contact with the punch 52 forms the machining marks 23d on the shear surface 23a. As the punch 52 further presses the metal sheet 40 in the thickness direction and the shearing advances, the fracture surface 23b is formed by the cut section of the metal sheet 40 and cracks are formed in the thickness direction of the metal sheet 40. This completes the shearing of the metal sheet 40.

When the shearing is completed, the metal plate 20 is formed with its side surface 23 including the shear surface 23a, the fracture surface 23b, and the droop surface 23c.

### Solder

As shown in FIGS. 1 to 4, the solder 30 joins the conductive pattern 13 and the metal plate 20. The conductive pattern 13 is arranged on the insulative substrate 12. Thus, the solder 30 joins the board 11 and the metal plate 20. The metal plate 20 is arranged on the board 11 so that the shear surface 23a is closer to the board 11 than the fracture surface 23b. Thus, the solder 30 joins the first plating layer 24 and the conductive pattern 13. Further, the solder 30 joins the shear surface 23a and the droop surface 23c of the side surface 23 with the conductive pattern 13.

The solder 30 electrically connects the conductive pattern 13 and the metal plate 20. The solder 30 includes a first edge 30a and a second edge 30b. The first edge 30a extends along the boundary of the shear surface 23a and the fracture surface 23b. The second edge 30b extends along the edge of the conductive pattern 13.

The solder 30 includes a solder fillet 31. The solder fillet 31 is formed from the conductive pattern 13 to the side surface 23 (shear surface 23a and droop surface 23c).

With reference to FIG. 1, P denotes the middle position of the solder fillet 31, in a side view, between the first edge 30a and the second edge 30b of the solder fillet 31. Further, in the side view of the solder fillet 31, an imaginary straight line connecting the first edge 30a to the second edge 30b will be referred to as the first imaginary line M, and an imaginary straight line lying along the middle position P and extending orthogonal to the first imaginary line M will be referred to as the second imaginary line N.

In the side view of the solder fillet 31, the solder fillet 31 is inwardly curved from the first edge 30a and the second edge 30b toward the middle position P. When the metal plate 20 is energized and heated, the heat is transferred by the solder fillet 31 to the board 11. This thermally expands the metal plate 20 and the board 11. Thus, stress is generated in the solder fillet 31. The stress may form cracks from the region near the middle position P. Such cracks may extend through the solder fillet 31 along the second imaginary line N.

The solder fillet 31 has a length L3 that is set so that cracks do not reach the conductive pattern 13. The length L3 of the solder fillet 31 is equal to the length of a perpendicular line T that extends from the first edge 30a to the conductive pattern 13. The length L3 of the solder fillet 31 is set to be greater than or equal to a length ensuring that breakage of the solder fillet 31 will not occur within the warranty period of the DC-DC converter in which the electronic device 10 is arranged. The length L3 of such a solder fillet 31 is determined in advance through experiments or the like. The warranty period of the DC-DC converter is the period during which operation of the DC-DC converter is ensured under a temperature environment to which the DC-DC converter is expected to be exposed. The length L3 of the solder fillet 31 may be set taking into consideration the device in which the electronic device 10 is arranged, the environment to which the electronic device 10 will be exposed, external factors such as vibration applied to the electronic device 10, and the like.

The first edge 30a of the solder fillet 31 is formed along the boundary of the shear surface 23a and the fracture surface 23b. Further, the solder 30 is arranged between the first plating layer 24 and the conductive pattern 13. Thus, the length L3 of the solder fillet 31 is greater than the length L1 of the shear surface 23a. The length L1 of the shear surface 23a is set so that the solder fillet 31 formed from the shear surface 23a to the board 11 has length L3. Thus, the solder fillet 31 ensures that the required length L3 will be obtained even though the solder fillet 31 is not formed on the fracture surface 23b. Accordingly, the length of the side surface 23 in the thickness direction, or the thickness of the metal plate 20, is set so that the solder fillet 31 is not formed on the fracture surface 23b. The thickness of the metal plate 20 is set to ensure that shearing will form the shear surface 23a with the required length L1. Formation of the shear surface 23a will determine the length L2 of the fracture surface 23b.

### Operation of Present Embodiment

When the metal plate 20 is soldered to the board 11, solder paste (not shown) is applied to the conductive pattern 13, and the distal end of the metal plate 20 is placed on the solder paste. The metal plate 20 is arranged on the board 11 so that the shear surface 23a is closer to the board 11 than the fracture surface 23b. In other words, the first main surface 21 faces the board 11. Specifically, the metal plate 20 is arranged so that the solder paste is sandwiched between the conductive pattern 13 and the first plating layer 24.

The solder paste is melted in a reflow oven or the like. The molten solder is wetly spread between the first plating layer 24 and the conductive pattern 13. Then, the molten solder is spread on the droop surface 23c and the machining marks 23d of the shear surface 23a toward the fracture surface 23b and reaches the boundary of the shear surface 23a and the fracture surface 23b. The molten solder also reaches the edge of the conductive pattern 13. Then, the molten solder is hardened. This solders and joins the metal plate 20 and the board 11, and forms the solder fillet 31.

The above-described embodiment has the following advantages.
(1) Even though the side surface 23 of the metal plate 20 is not plated, the solder fillet 31 can be formed from the shear surface 23a to the board 11 using the machining marks 23d of the shear surface 23a. Thus, the production cost for soldering the metal plate 20 to the board 11 is lower than when the side surface 23 of the metal plate 20 is plated to form the solder fillet 31.
(2) The thickness of the metal plate 20 is set so that the fillet 31 is not formed on the fracture surface 23b. Thus, the solder fillet 31 is not formed on the entire side surface 23 of the metal plate 20 in the thickness direction.
(3) The metal plate 20 is formed by shearing the plated metal sheet 40. By merely shearing the metal sheet 40, the metal plate 20 is formed including the plated first and second main surfaces 21 and 22, the shear surface 23a, and the fracture surface 23b. The metal plate 20 is manufactured in the present embodiment more easily than, with, for example, a manufacturing method that first shears a non-plated metal sheet to form the shear surface 23a and the fracture surface 23b, and then plates the first main surface 21 and the second main surface 22 while avoiding plating of the shear surface 23a and the fracture surface 23b.

The present embodiment may be modified as follows. The present embodiment and the following modifications can be combined if the combined modifications remain technically consistent with each other.

The metal plate 20 includes the first plating layer 24, which coats the first main surface 21, and the second plating layer 25, which coats the second main surface 22. Instead, the first main surface 21 and the second main surface 22 may both be free from a plating layer. Alternatively, a plating layer may be applied to only one of the first main surface 21 and the second main surface 22.

The metal plate 20 may be formed through the following procedure. A non-plated sheet is first sheared to obtain a metal plate that includes the shear surface 23a and the fracture surface 23b on the side surface. Then, the first main surface 21 and the second main surface 22 of the obtained metal plate are plated.

The thickness of the metal plate 20 may be set so that the solder fillet 31 is formed from the board 11 to part of the fracture surface 23b.

The first edge 30a of the solder fillet 31 may be inside the region of the shear surface 23a instead of being arranged at the boundary between the shear surface 23a and the fracture surface 23b. In other words, the solder fillet 31 may cover the entire region of the shear surface 23a or partially cover the region of the shear surface 23a.

In a side view of the solder fillet 31, the solder fillet 31 may be outwardly curved and from the first edge 30a and the second edge 30b toward the middle position P or extend straight from the first edge 30a to the second edge 30b.

In the electronic device 10, a conductive pattern 13 may be arranged on each of the two surfaces of the insulative substrate 12, and a metal plate 20 may be soldered to each of the two surfaces of the board 11. In this case, at least one of the metal plates 20 is arranged on the board 11 so that the shear surface 23a is closer to the board 11 than the fracture surface 23b.

The electronic device 10 may be arranged in an inverter.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. An electronic device, comprising:
a board; and
a flat metal plate soldered to the board, wherein
the metal plate includes
a first main surface,
a second main surface opposite to the first main surface, and
a side surface that connects the first main surface and the second main surface,
the side surface includes a shear surface and a fracture surface,
the metal plate is arranged on the board so that the shear surface is closer to the board than the fracture surface, and
a solder fillet is formed from the board to the shear surface.

2. The electronic device according to claim 1, wherein the side surface has a length in a direction that extends from the first main surface to the second main surface, and the length of the side surface is set so that the solder fillet is not formed on the fracture surface.

3. The electronic device according to claim 1, wherein the metal plate is formed by shearing a metal sheet in a thickness direction, the metal sheet having two opposite surfaces in the thickness direction that are plated.

4. The electronic device according to claim 1, wherein the shear surface and the fracture surface are arranged next to each other in a direction extending from the first main surface to the second main surface.

5. The electronic device according to claim 1, wherein the solder fillet includes an edge that extends along a boundary of the shear surface and the fracture surface or an edge that extends inside a region of the shear surface.
